(19) United States
(12) Patent Application Publication
(10) Pub. No.: US 2019/0006457 A1
(43) Pub. Date: Jan. 3, 2019

(54) PACKAGE INTEGRATED PASSIVES

(71) Applicant: Intel Corporation, Santa Clara, CA (US)

(72) Inventors: Aleksandar Aleksov, Chandler, AZ (US); Kristof Darmawikarta, Chandler, AZ (US); Robert Alan May, Chandler, AZ (US); Sandeep Gaan, Phoenix, AZ (US)

(21) Appl. No.: 15/638,044

(22) Filed: Jun. 29, 2017

(51) Int. Cl. H01L 49/02; H01L 23/522

(52) U.S. Cl. CPC H01L 28/24; H01L 23/522; H01L 28/60

(57) ABSTRACT

A semiconductor device may include a plurality of layers of a substrate. A die may be coupled to at least one of the plurality of layers of the substrate. A passive electrical component may be integrally formed within the layers of the substrate. The passive electrical component may be a resistor or a capacitor. One or more conductors may be configured to allow electrical communication between the passive electrical component and the die. The one or more conductors may be integrally formed within the plurality of layers of the substrate.

### BACKGROUND

Passives components, such as resistors and capacitors, are key components to the overall electrical functionality of an assembled semiconductor packaging. Typically these passives are fabricated separately or bought from a supplier, and subsequently are embedded in the package or attached on the surface of the package.

### SUMMARY

### Brief Description of the Drawings

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 is a schematic view of a semiconductor device 100 including a first layer 121 of a substrate 120.

FIG. 2 is a schematic view of a semiconductor device 100 including a plurality of layers of the substrate 120.

FIG. 3 illustrates a portion of a passive component 300 during a manufacturing operation.

FIG. 4 illustrates a portion of the passive component 300 of FIG. 3 during an additional manufacturing operation.

FIG. 5 illustrates a portion of the passive component 300 of FIG. 4 during an additional manufacturing operation.

FIG. 6 illustrates a portion of the passive component 300 of FIG. 5 during an additional manufacturing operation.

FIG. 7 illustrates a portion of the passive component 300 of FIG. 6 during an additional manufacturing operation.

FIG. 8 illustrates a portion of the passive component 300 of FIG. 7 during an additional manufacturing operation.

FIG. 9 illustrates a portion of the passive component 300 of FIG. 8 during an additional manufacturing operation.

FIG. 10 illustrates a portion of the passive component 300 of FIG. 9 during an additional manufacturing operation.

FIG. 11 illustrates a portion of the passive component 1100 during a manufacturing operation.

FIG. 12 illustrates a portion of the passive component 1100 of FIG. 11 during an additional manufacturing operation.

FIG. 13 illustrates a portion of the passive component 1100 of FIG. 12 during an additional manufacturing operation.

FIG. 14 illustrates a portion of the passive component 1100 of FIG. 13 during an additional manufacturing operation.

FIG. 15 illustrates a portion of the passive component 1100 of FIG. 14 during an additional manufacturing operation.

FIG. 16 illustrates a portion of the passive component 1100 of FIG. 15 during an additional manufacturing operation.

FIG. 17 illustrates a portion of the passive component 1100 of FIG. 16 during an additional manufacturing operation.

FIG. 18 illustrates a portion of the passive component 1100 of FIG. 17 during an additional manufacturing operation.

FIG. 19 illustrates a system level diagram, depicting an example of an electronic device (e.g., system) including either the semiconductor device 100.

### DETAILED DESCRIPTION

Utilization of passive components in relation to semiconductor packages may require complex embedding schemes, occupy valuable packaging space, increase the overall dimensions of the package, and may be expensive.

The present inventors have recognized, among other things, that a problem to be solved may include reducing semiconductor package complexity, minimizing package dimensions, reduce costs, and improve performance of the performance of packaging. The present subject matter may help provide a solution to these problems, such as by utilizing a semiconductor device according to the present subject matter. Additionally, the semiconductor device may reduce losses by providing shorter electrical communication pathways. Further, the semiconductor device may allow for the removal of solder joint interconnects and/or pads to connect passive components to other devices (e.g., a die). Still further, the semiconductor device may allow for passive devices to be integrally formed within layers of a substrate, thereby minimizing package dimensions. Still yet further, utilization of the semiconductor device may reduce variations in electrical properties (e.g., resistance or capacitance) between individual passive components.

The semiconductor device may include a plurality of layers of a substrate. A die may be coupled to at least one of the plurality of layers of the substrate. A passive electrical component may be integrally formed within the layers of the substrate. The passive electrical component may be a resistor or a capacitor. One or more conductors may be configured to allow electrical communication between the passive electrical component and the die. The one or more conductors may be integrally formed within the plurality of layers of the substrate.

Aspect 1 may include or use subject matter (such as an apparatus, a system, a device, a method, a means for performing acts, or a device readable medium including instructions that, when performed by the device, may cause the device to perform acts), such as may include or use a semiconductor device. The semiconductor device may include a plurality of layers of a substrate. The semiconductor device may include a die coupled to at least one of the plurality of layers of the substrate. The semiconductor device may include a passive electrical component integrally formed within the layers of the substrate. The semiconductor device may include one or more conductors configured to allow electrical communication between the passive electrical component and the die. The one or more conductors may be integrally formed within the plurality of layers of the substrate.

Aspect 2 may include or use, or may optionally be combined with the subject matter of Aspect 1, to optionally include or use that the passive component may be in electrical communication with an external device.

Aspect 3 may include or use, or may optionally be combined with the subject matter of one or any combination of Aspects 1 or 2 to optionally include or use that the passive electrical component may be included in a plurality of passive electrical components.

Aspect 4 may include or use, or may optionally be combined with the subject matter of one or any combination of Aspects 1 through 3 to optionally include or use that the passive component may be a resistor.

Aspect 5 may include or use, or may optionally be combined with the subject matter of one or any combination of Aspects 1 through 4 to optionally include or use that a resistor may include a resistive component. The resistive component may be formed from a portion of a layer of the substrate. The resistor may include a first electrode and a second electrode. The first electrode and the second electrode may be coupled to the resistive component such that the first and second electrodes are in electrical communication through the resistive component.

Aspect 6 may include or use, or may optionally be combined with the subject matter of one or any combination of Aspects 4 through 5 to optionally include or use that the layer of the substrate may be a first layer of the substrate. The semiconductor device may include a second layer of the substrate. The second layer of the substrate may be coupled to the first layer of the substrate. The second layer of the substrate may be coupled to the resistive component. The second layer of the substrate may be coupled to the first and second electrodes. A portion of the first electrode and/or the second electrode may be exposed by the second layer of the substrate.

Aspect 7 may include or use, or may optionally be combined with the subject matter of one or any combination of Aspects 4 through 6 to optionally include or use that the resistive component may comprise a material including: titanium nitride, combinations of titanium and nitrogen in a form, nickel, nickel phosphorous, tantalum, and bismuth.

Aspect 8 may include or use, or may optionally be combined with the subject matter of one or any combination of Aspects 1 through 3 to optionally include or use that the passive component may be a capacitor.

Aspect 9 may include or use, or may optionally be combined with the subject matter of one or any combination of Aspects 1 through 3, or Aspect 8 to optionally include or use that the capacitor may include a first package layer comprising the substrate. The capacitor may include a second package layer. The second package layer may include a first electrode. The first electrode may be coupled to the first package layer. The second package layer may include a second layer of the substrate. The second layer of the substrate may substantially surround the first electrode. The capacitor may include a third package layer. The third package layer may include a dielectric component. The dielectric component may be coupled to the first electrode. The third package layer may include a second electrode. The second electrode may be coupled to the dielectric component. The third layer may include a third layer of the substrate. The third layer of the substrate may be coupled to the second electrode.

Aspect 10 may include or use, or may optionally be combined with the subject matter of one or any combination of Aspects 8 through 9 to optionally include or use that the dielectric component may have a first dielectric constant. The semiconductor device may include a second dielectric component having a second dielectric constant.

Aspect 11 may include or use, or may optionally be combined with the subject matter of Aspect 10 to optionally include or use that the first dielectric constant may be different than the second dielectric constant.

Aspect 12 may include or use, or may optionally be combined with the subject matter of one or any combination of Aspects 10 through 11 to optionally include or use that the first dielectric component and the second dielectric component may be located on the same layer of the substrate.

Aspect 13 may include or use, or may optionally be combined with the subject matter of one or any combination of Aspects 8 through 12 to optionally include or use that the second electrode may substantially surround the dielectric component.

Aspect 14 may include or use, or may optionally be combined with the subject matter of one or any combination of Aspects 8 through 13 to optionally include or use that the first electrode and the second electrode may have the same height with respect to the layer of the substrate.

Aspect 15 may include or use, or may optionally be combined with the subject matter of one or any combination of Aspects 8 through 15 to optionally include or use that the semiconductor package may be a first semiconductor package. The first semiconductor package may be coupled to a second semiconductor package.

Aspect 16 may include or use subject matter (such as an apparatus, a system, a device, a method, a means for performing acts, or a device readable medium including instructions that, when performed by the device, may cause the device to perform acts), such as may include or use a semiconductor device. The semiconductor device may include a plurality of layers of a substrate. The semiconductor device may include a die. The die may be coupled to at least one of the plurality of layers of the substrate. The semiconductor device may include a resistor. The resistor may be integrally formed within the layers of the substrate. The resistor may include a resistive component. The resistive component may be formed from a portion of a layer of the substrate. The resistor may include a first electrode and a second electrode. The first and second electrode may be coupled to the resistive component such that the first and second electrodes are in electrical communication through the resistive component. The resistor may include one or more conductors. The one or more conductors may be configured to establish an electrical communication pathway between the resistor and the die. The one or more conductors may be integrally formed within the plurality of layers of the substrate.

Aspect 17 may include or use, or may optionally be combined with the subject matter of Aspect 16, to optionally include or use that a length of the resistive component may be at least 1.5 times greater than a width of the resistive component. Aspect 18 may include or use, or may optionally be combined with the subject matter of one or any combination of Aspects 16 or 17 to optionally include or use that the layer of the substrate is a first layer of the substrate. The semiconductor device may include a second layer of the substrate. The second layer of the substrate may be coupled to the first layer of the substrate. The second layer of the substrate may be coupled the resistive component. The second layer of the substrate may be coupled the first and second electrodes. A portion of the first electrode and the second electrode may be exposed by the second layer of the substrate.

Aspect 19 may include or use, or may optionally be combined with the subject matter of one or any combination of Aspects 16 through 18 to optionally include or use that the resistive component may comprise a material including: Titanium nitride, Nickel Phosphorous, Bismuth.

Aspect 20 may include or use subject matter (such as an apparatus, a system, a device, a method, a means for performing acts, or a device readable medium including instructions that, when performed by the device, may cause the device to perform acts), such as may include or use a semiconductor device. The semiconductor device may include a plurality of layers of a substrate. The semiconductor device may include a die. The die may be coupled to at least one of the plurality of layers of the substrate. The semiconductor device may include a capacitor. The capacitor may be integrally formed within the layers of the substrate. The capacitor may include a first electrode. The first electrode may be formed from a portion of a first layer of the plurality of layers of the substrate. The capacitor may include a dielectric component. The dielectric component may be coupled to the first electrode. The capacitor may include a second electrode. The second electrode may be coupled to the dielectric component. The capacitor may include one or more conductors. The one or more conductors may be configured to allow electrical communication between the capacitor and the die. The one or more conductors may be integrally formed within the plurality of layers of the substrate.

Aspect 21 may include or use, or may optionally be combined with the subject matter of Aspect 20, to optionally include or use that the dielectric component has a first dielectric constant. The semiconductor device may include a second layer of the plurality of layers of the substrate. The second layer may be coplanar with the dielectric component. The first dielectric component may have a first dielectric constant. The second layer may have a second dielectric constant. Aspect 22 may include or use, or may optionally be combined with the subject matter of one or any combination of Aspects 20 or 21 to optionally include or use that the first dielectric constant may be different than the second dielectric constant.

Aspect 23 may include or use, or may optionally be combined with the subject matter of one or any combination of Aspects 20 through 22 to optionally include or use that the first dielectric component and the second dielectric component may be located on the same layer of the substrate.

Aspect 24 may include or use, or may optionally be combined with the subject matter of one or any combination of Aspects 20 through 23 to optionally include or use that the second electrode substantially surrounds the dielectric component.

Aspect 25 may include or use subject matter (such as an apparatus, a system, a device, a method, a means for performing acts, or a device readable medium including instructions that, when performed by the device, may cause the device to perform acts), such as may include or use a method for integrally forming a passive component within a package. The method may include depositing a resistive component on a first layer of substrate. The method may include depositing a layer of conductive material on the resistive component. The method may include removing a portion of the layer of conductive material.

Aspect 26 may include or use, or may optionally be combined with the subject matter of Aspect 25, to optionally include or use that the layer of conductive material is a first layer of conductive material. The method may include depositing a second layer of conductive material.

Aspect 27 may include or use, or may optionally be combined with the subject matter of one or any combination of Aspects 25 or 26 to optionally include or use depositing a second layer of substrate. The second layer of substrate may be coupled to the first layer of substrate, the first electrode, the second electrode, and the resistive component.

Aspect 28 may include or use, or may optionally be combined with the subject matter of one or any combination of Aspects 25 through 27 to optionally include or use that the depositing the resistive component or depositing the layer of conductive material may include depositing the resistive component or the conductive material using a process including: electrodepositing, electroless plating, physical depositing, additive processes, and subtractive processes.

Aspect 29 may include or use, or may optionally be combined with the subject matter of one or any combination of Aspects 25 through 28 to optionally include or use that the resistive component may be a different material than the conductive material.

Aspect 30 may include or use, or may optionally be combined with the subject matter of one or any combination of Aspects 25 through 29 to optionally include or use that removing the portion of the layer of conductive material may create a first electrode and a second electrode from the layer of conductive material

Aspect 31 may include or use, or may optionally be combined with the subject matter of one or any combination of Aspects 25 through 30 to optionally include or use that removing the portion of the layer of conductive material may include removing the layer of conductive material between the first electrode and the second electrode.

Aspect 32 may include or use, or may optionally be combined with the subject matter of one or any combination of Aspects 25 through 27 to optionally include or use that the layer of conductive material may be selectively patterned to create the first electrode and the second electrode.

Aspect 33 may include or use, or may optionally be combined with the subject matter of one or any combination of Aspects 25 through 32 to optionally include or use that depositing the resistive component may include sputtering the resistive component onto the first layer of substrate.

Aspect 34 may include or use, or may optionally be combined with the subject matter of one or any combination of Aspects 25 through 33 to optionally include or use that a length of the resistive component may at least 2 times greater than a width of the resistive component.

Aspect 35 may include or use subject matter (such as an apparatus, a system, a device, a method, a means for performing acts, or a device readable medium including instructions that, when performed by the device, may cause the device to perform acts), such as may include or use a method for integrally forming a passive component within a package. The method may include depositing a first electrode on a first layer of substrate. The method may include depositing a dielectric component on the first electrode. The method may include depositing a second electrode on the dielectric component.

Aspect 36 may include or use, or may optionally be combined with the subject matter of Aspect 35, to optionally include or use depositing a second layer of substrate. The second layer of substrate may be coupled to the first electrode and the first layer of substrate.

Aspect 37 may include or use, or may optionally be combined with the subject matter of one or any combination of Aspects 35 or 36 to optionally include or use that depositing the first electrode, depositing the dielectric component, or depositing the second electrode may include depositing the first electrode, the dielectric component, or the second electrode may include using a process including: electrodepositing, electroless plating, physical depositing, additive processes, and subtractive processes.

Aspect 38 may include or use, or may optionally be combined with the subject matter of one or any combination of Aspects 35 through 37 to optionally include or use removing a portion of the dielectric component.

Aspect 39 may include or use, or may optionally be combined with the subject matter of one or any combination of Aspects 35 through 38 to optionally include or use that the second electrode may substantially surround the dielectric component.

Aspect 40 may include or use, or may optionally be combined with the subject matter of one or any combination of Aspects 35 through 39 to optionally include or use that depositing a second electrode may include coupling the second electrode with a portion of a second layer of substrate.

Aspect 41 may include or use, or may optionally be combined with the subject matter of one or any combination of Aspects 35 through 40 to optionally include or use coupling a first via to the first electrode and a second via to the second electrode.

Aspect 42 may include or use, or may optionally be combined with the subject matter of one or any combination of Aspects 35 through 41 to optionally include or use depositing a third layer of the substrate. The third layer of substrate may be coupled to the second electrode, the first via, and/or the second via. A portion of the first via and a portion of the second via may be exposed.

Aspect 42 may include or use, or may optionally be combined with the subject matter of Aspect 42 to optionally include or use that the exposed portions of the first via and the second via may be coplanar with a top surface of the third layer of the substrate.

Aspect 43 may include or use, or may optionally be combined with any portion or combination of any portions of any one or more of Aspects 1 through 42 to include or use, subject matter that may include means for performing any one or more of the functions of Aspects 1 through 42, or a machine-readable medium including instructions that, when performed by a machine, cause the machine to perform any one or more of the functions of Aspects 1 through 42.

Each of these non-limiting examples may stand on its own, or may be combined in various permutations or combinations with one or more of the other examples. This overview is intended to provide an overview of subject matter of the present patent application. It is not intended to provide an exclusive or exhaustive explanation of the present subject matter.

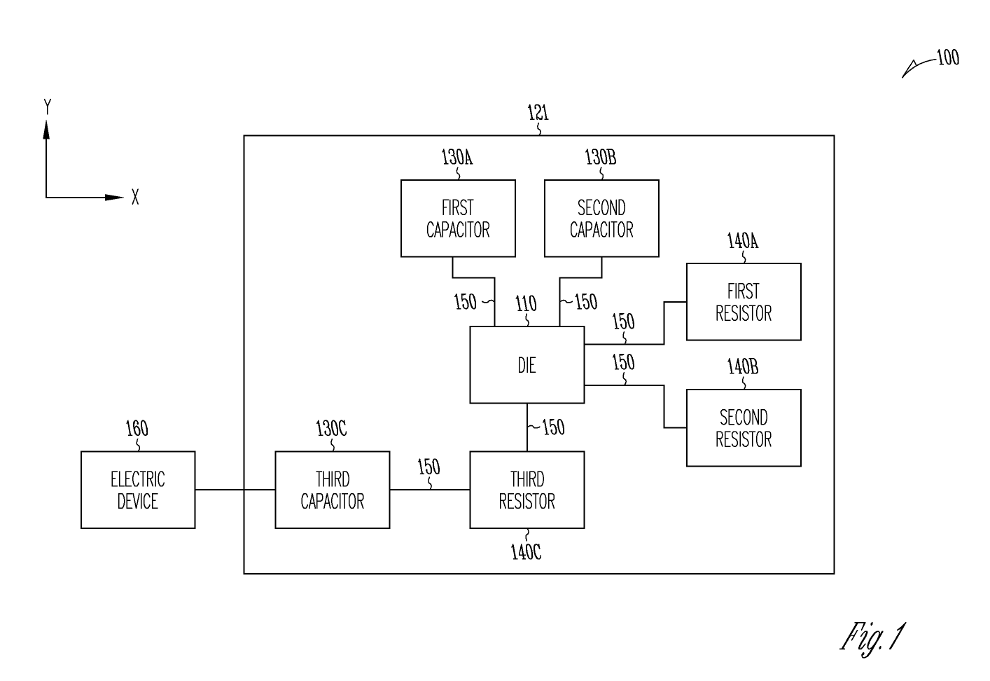

FIG. 1 is a schematic view of a semiconductor device 100 including a first layer 121 of a substrate 120. The elements shown in FIG. 1 may not necessarily be drawn to scale. The first layer 121 of the substrate 120 may be included in a plurality of layers of the substrate 120. A die 110 may be coupled to at least one of the plurality of layers of the substrate 120 (e.g., the first layer 121). The semiconductor device 100 may include one or more passive components. The one or more passive components may include a resistor or a capacitor. For instance, the semiconductor device 100 may include a first capacitor 130A, a second capacitor 130B, and a third capacitor 130C, but is not so limited. Additionally, the semiconductor device 100 may include a first resistor 140A, a second resistor 140B, and a third resistor 140C, but is not so limited. The substrate 120 may include a buildup film, a dry film resist, an epoxy, silicon, silica, dielectric, or the like.

The one or more conductors may allow for the electrical communication between the passive components and the die 110. For instance, the first capacitor 130A, the second capacitor 130B, and the third capacitor 130C may be in electrical communication with the die 110. Additionally, the first resistor 140A, the second resistor 140B, and the third resistor 140C may be in electrical communication with the die 110. Further, the passive components may be in electrical communication with each other. In an example, the third capacitor 130C may be in electrical communication with the third resistor 140C and the die 110 through the one or more conductors 150. Still further, the one or more conductors 150 may allow for the semiconductor device 100 to be in electrical communication with an external device (e.g., an antenna, a system-in-a-package)

The passive electrical components (e.g., the first capacitor 130A and the first resistor 140A) may be integrally formed within the plurality of layers of the substrate 120. The one or more conductors 150 may be integrally formed within the plurality of layers of the substrate 120. Integrally forming a component within the plurality of layers of the substrate 120 may include manufacturing a component (e.g., the first resistor 140A, the first capacitor 130A, or the one or more conductors 150) such that the substrate 120 substantially encloses (e.g., surrounds, encases, or is implanted within) the component. Integrally forming a component within the plurality of layers of the substrate 120 may include manufacturing a component such that the substrate 120 entirely encloses the component such that the component is entirely inaccessible, or unable to be seen, from the exterior of the semiconductor device 100. However, integrally forming a passive component within the plurality of layers of the substrate 120 may include manufacturing a component such that a portion of the component is exposed within the substrate 120 (e.g., a surface of the component may be accessible from the exterior of the semiconductor device 100). The components may be included within a single layer (e.g., the first layer 121) of the substrate 120. The components may be located anywhere within the layer, and are not so limited by the positions shown in FIG. 1 or 2. As is discussed herein, the components may be included in more than one layer of the substrate 120.

FIG. 2 is a schematic view of a semiconductor device 100 including a plurality of layers of the substrate 120. The die 110 may be coupled to a layer (e.g., the first layer 121) of the substrate 120. The elements shown in FIG. 2 may not necessarily be drawn to scale. The plurality of layers of the substrate 120 may include the first layer 121 of FIG. 1, a second layer 122, a third layer 123, and a fourth layer 124. The semiconductor device 100 may include additional or fewer layers of the substrate 120. In an example, the passive electrical components or the one or more conductors 150 may span more than one layer of the substrate 120. In an example, a fourth resistor 140D may be included within the first layer 121 and the second layer 122. In another example, a fourth capacitor 130D may be included within the first layer 121, the second layer 122, and the third layer 123. Additional components (e.g., the second capacitor 130B or the one or more conductors 150) may span more than one layer of the substrate 120. The die 110 may be in electrical communication with passive components on more than one layer of the substrate 120 (e.g., the first layer 121 and the second layer 122).

The passive components (e.g., the fourth resistor 140D and/or the fourth capacitor 130D) may be located anywhere within the plurality of layers. As shown in FIG. 2, the fourth resistor 140D, the fourth capacitor 130D, and a fifth capacitor 130E may be positioned underneath the die 110. In contrast the passive components shown in FIG. 1 (e.g., the first resistor 140A and the first capacitor 130A are positioned at the periphery of the die 110. The semiconductor device 100 may be a first semiconductor device. The first semiconductor device may be coupled to a second semiconductor device.

In an example, the fourth capacitor 130D may include a first dielectric component (not shown). The fifth capacitor 130E may include a second dielectric component (not shown). The first dielectric component and the second dielectric component may each have a top and a bottom surface. The top and bottom surfaces of the first dielectric component and the second dielectric component may be coplanar. The first dielectric component and the second dielectric component may be included in the same layer (e.g., the first layer 121). The first dielectric component and the second dielectric component may be included in different layers (e.g., the first dielectric component is positioned in the first layer 121 and the second dielectric component is positioned in the second layer 122). The first dielectric component may have a first dielectric constant (e.g., relative permittivity). The second dielectric component may have a second dielectric constant. The substrate 120 may have a third dielectric constant. The first dielectric constant may be the same as the second dielectric constant. The first dielectric constant may be different than the second dielectric constant. The third dielectric constant may be the same as the first dielectric constant or the second dielectric constant. The third dielectric constant may be different than the first dielectric constant or the second dielectric constant.

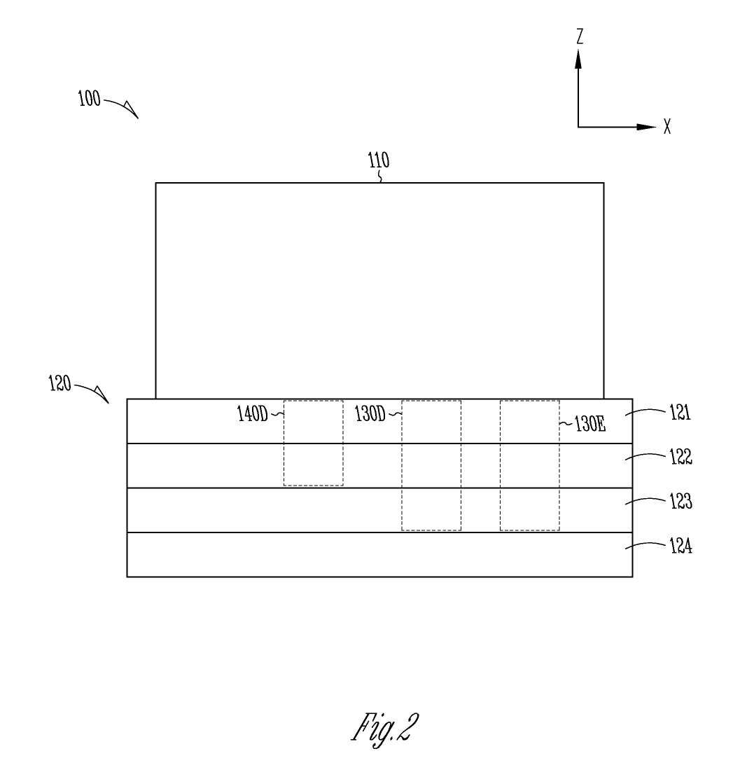

FIG. 3 illustrates a portion of a passive component 300 during a manufacturing operation. The passive component 300 may be a resistor. The passive component 300 may be the first resistor 140A of FIG. 1. The passive component 300 may include a substrate 320, a resistive component 330 and a layer of conductive material 340. The substrate 320 may include the same material as the substrate 120 of FIGS. 1-2. The substrate 320 may be one of the plurality of layers of the substrate 120 of FIG. 1. In an example, the substrate 320 may be the first layer 121 of the substrate 120 of FIG. 1. In another example, the substrate 320 may be the second layer 122 of the substrate 120 of FIG. 1.

The resistive component 330 may be formed from a portion (e.g., first layer 121 of FIG. 1) of the substrate 320. The resistive component 330 may be formed on, and thereby coupled with, the substrate 320. The resistive component 330 may be formed onto the substrate 320 by a process including electrodepositing, sputtering, electro-less plating, physical deposition, additive processes, and subtractive processes. However, other processes are possible to couple the resistive component 330 with the substrate 320 (or form the resistive component 330 from the substrate 320), and are anticipated within the scope of this disclosure. The resistive component 330 may include titanium, titanium nitride, combinations of titanium and nitrogen in a form (e.g., TiₓNi₁₋ₓ), nickel, nickel phosphorous, combinations of nickel and phosphorous in a form, tantalum, bismuth, carbon/graphite, ITO, ZTO, IGZO, and/or IZO (or the like). The resistive component 330 may be parallel with the substrate 320.

A length (e.g., the dimension along the X-axis of FIG. 3) of the resistive component 330 may be ten times a width (e.g., the dimension orthogonal to the X and Z axis of FIG. 3, or the dimension perpendicular to the sheet) of the resistive component 320. However, the present subject matter is not so limited, and other length-to-width ratios are possible (e.g., the length being 1.5 times the width, or the length being equal to the width) and anticipated within the scope of this disclosure.

The layer of conductive material 340 may be coupled to the resistive component 330. The layer of conductive material 340 may be formed on, and thereby coupled with, the resistive component 330. The layer of conductive material 340 may be formed on the resistive component 330 by a process including electrodepositing, sputtering, electro-less plating, physical deposition, additive processes, and subtractive processes. However, other processes are possible to couple the layer of conductive material 340 with the resistive component 330 (or form the layer of conductive material 340 from resistive component 330), and are anticipated within the scope of this disclosure. The layer of conductive material 340 may include copper and/or aluminum. The layer of conductive material 340 may be parallel with the resistive component 330. The layer of conductive material 340 may be parallel with the substrate 320. The layer of conductive material 340 may be comprised of a different material than the resistive component 330. The passive component 300 may also include additional materials (e.g., barrier metals) at an interface (e.g., between the substrate 320 and the layer of conductive material 340, or between the layer of conductive material 340 and the resistive component 330) configured to enhance material compatibility.

FIG. 4 illustrates a portion of the passive component 300 of FIG. 3 during an additional manufacturing operation. A thickness of the layer of conductive material 340 may be increased (e.g., increasing the dimensions of the layer of conductive material 340 along the Z-axis of FIG. 4). The thickness of the layer of conductive material may be increased by depositing (or coupling) additional conductive material upon the layer of conductive material 340. The layer of conductive material 340 may have a resistor area 345 patterned upon the layer of conductive material 340. The thickness of the layer of conductive material 340 may be increased only in the resistor area 345. Stated another way, the layer of conductive material 340 may have a first thickness and a second thickness. The second thickness may be greater than the first thickness. The second thickness may correspond with (e.g., have the same dimensions along the X-axis of FIG. 4 as) the resistor area 345.

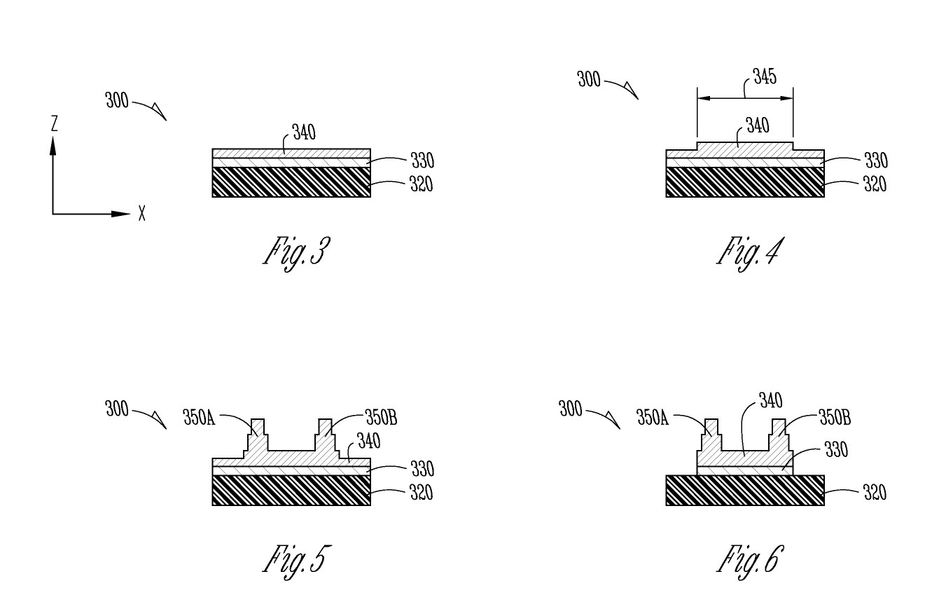

FIG. 5 illustrates a portion of the passive component 300 of FIG. 4 during an additional manufacturing operation. The passive component 300 may include a first electrode 350A and a second electrode 350B. The first electrode 350A and the second electrode 350B may be coupled to (e.g., formed from) the layer of conductive material 340. The first electrode 350A and the second electrode 350B may be deposited onto the layer of conductive material 340. The first electrode 350A and the second electrode 350B may each have a varying length (e.g., along the X-axis of FIG. 5) along the height (e.g., along the Z-axis of FIG. 5) of the first electrode 350A and the second electrode 350B. As shown in FIG. 5, the first electrode 350A and the second electrode 350B each have a first length and a second length.

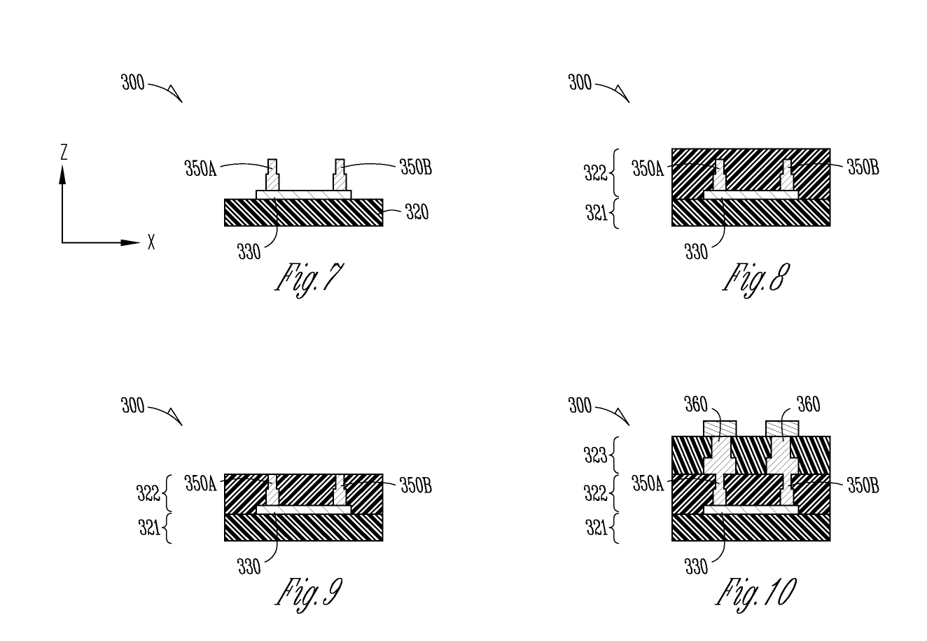

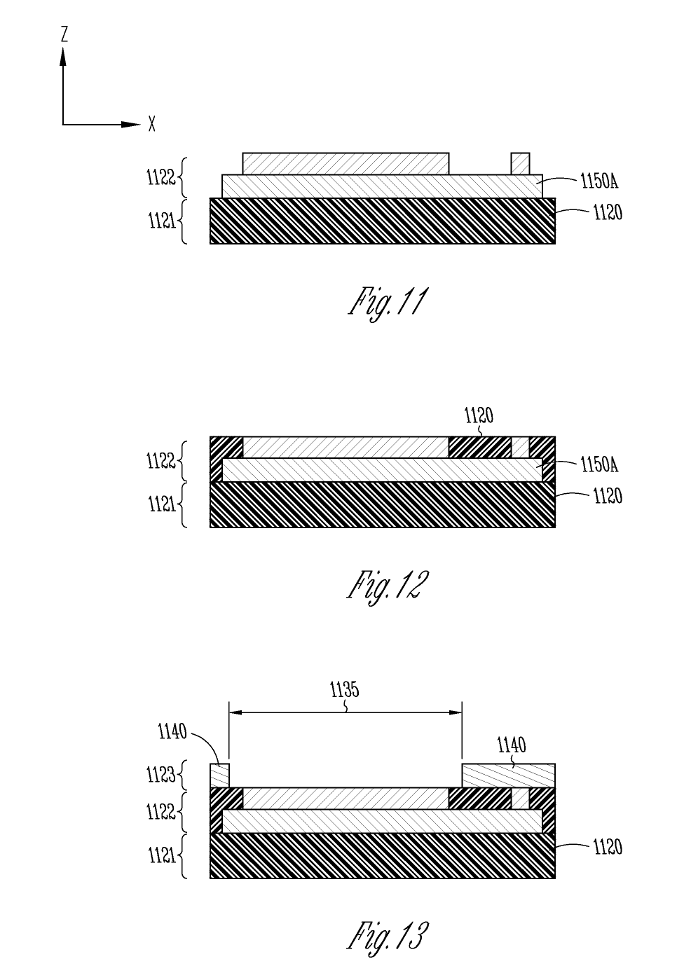

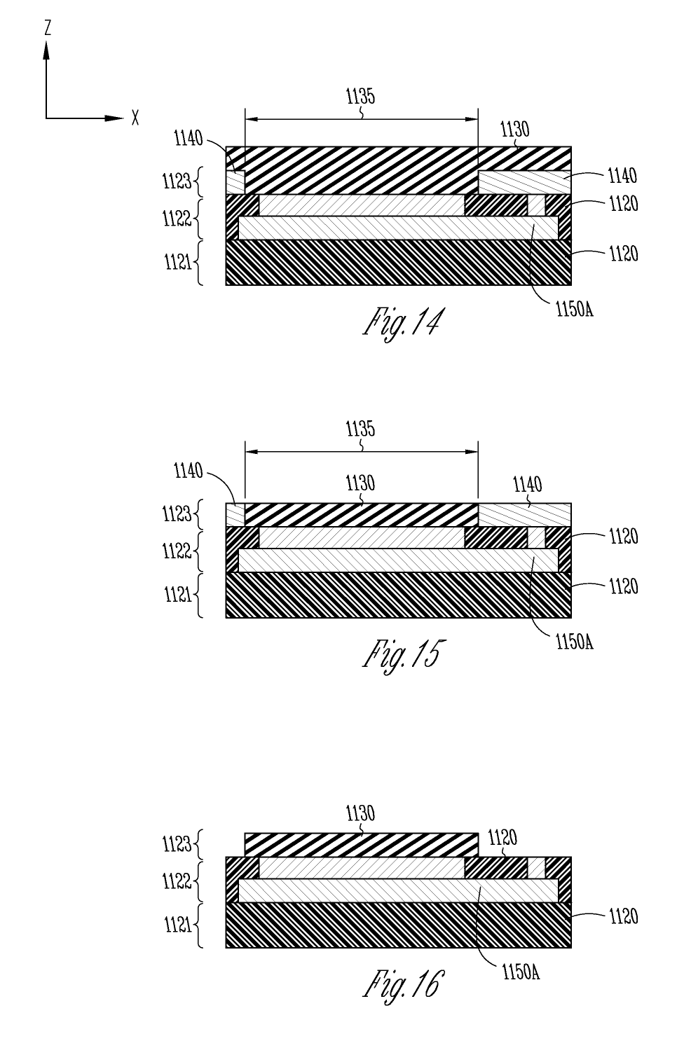

FIG. 6 illustrates a portion of the passive component 300 of FIG. 5 during an additional manufacturing operation. As shown in FIG. 5, the portions of the conductive layer 340 and the resistive component 330 outside the resistor area 345 may be removed. The portions of the conductive layer 340 and the resistive component 330 outside the resistor area 345 may be etched away. The conductive layer 340 may be removed prior to the resistive component being removed. Removal of a portion of the conductive layer 340 may simultaneously reduce the dimensions (e.g., the length) of the first electrode 350A and the second electrode 350B. Removal of the conductive layer 340 and the resistive component 330 outside the resistor area 345 may expose portions of the substrate 320.

FIG. 7 illustrates a portion of the passive component 300 of FIG. 6 during an additional manufacturing operation. As shown in FIG. 7, the layer of conductive material 340 between the first electrode 350A and the second electrode 350B (shown in FIGS. 5 and 6) may be removed. Removal of the layer of conductive material 340 between the first electrode 350A and the second electrode 350B may establish an electrical communication pathway between the first electrode 350A and the second electrode 350B through the resistive component 330. Stated another way, by removing the layer of conductive material 340 between the first electrode 350A and the second electrode 350B, the passive component 300 is no longer configured to allow the electrical communication of the first electrode 350A and the second electrode 350B through the layer of conductive material 340 and the resistive component 330. Instead, removing the layer of conductive material 340 between the first electrode 350A and the second electrode 350B configures the passive component 300 to allow the electrical communication between the first electrode 350A and the second electrode 350B only through the resistive component 300.

Allowing the electrical communication between the first electrode 350A and the second electrode 350B only through the resistive component 300 may allow for the passive component 300 to function as a resistor. The resistive component 300 may produce an impedance between the first electrode 350A and the second electrode 350B. The impedance between the first electrode 350A and the second electrode 350B may range from 25 ohms to 100 ohms, but is not so limited. Alteration of the dimensions of the resistive component 340 may alter the impedance that is experienced between the first electrode 350A and the second electrode 350B. Implementation of the passive component 300 within an electronic device (e.g., the semiconductor device 100 of FIGS. 1 and 2) may allow for precise impedances to be established between the first electrode 350A and the second electrode 350B. Precise impedances between the first electrode 350A and the second electrode 350B may be important in certain instances, such as power transformation within the electronic device.

FIG. 8 illustrates a portion of the passive component 300 of FIG. 7 during an additional manufacturing operation. In an example, the substrate 320 shown in FIGS. 3 through 7 may be a first layer 321 of the substrate 320. The first layer 321 of the substrate 320 may correspond with the first layer 121 of the substrate 120 of FIG. 1. The passive component 300 may include a second layer 322 of the substrate 320. The second layer 322 of the substrate 320 may correspond with the second layer 122 of the substrate 120 of FIG. 1. The first layer 321 and the second layer 322 of the substrate 320 may be included in a plurality of layers of the substrate 320.

As shown in FIG. 8, the second layer 322 of the substrate 320 may be coupled with the first layer 321 of the substrate 320, the resistive component 330, the first electrode 350A, and the second electrode 350B. The second layer 322 of the substrate 320 may fill the space between the first electrode 350A and the second electrode 350B. The coupling of the second layer 322 of the substrate 320 with the first layer 321 of the substrate 320, the resistive component 330, the first electrode 350A, and the second electrode 350B integrally forms the passive component 300 within the plurality of layers of the substrate 320. As described herein, the passive component 300 may be completely or partially enclosed by the substrate 320.

FIG. 9 illustrates a portion of the passive component 300 of FIG. 8 during an additional manufacturing operation. As shown in FIG. 9, the second layer 322 of the substrate 320 may be planarized. Planarizing the second surface 322 may include removing a portion of the second layer 322 of the substrate 320 such that the top surface of the second layer 322 is coplanar with the top surface the first electrode 350A and the top surface of the second electrode 350B. Planarizing the second surface may expose portions (e.g., the top surfaces) of the first electrode 350A and the second electrode 350B. Exposing portions of the first electrode 350A and the second electrode 350B may allow for additional structures, such as traces or vias, to be coupled to, and facilitate the electrical communication with, the first electrode 350A and the second electrode 350B.

FIG. 10 illustrates a portion of the passive component 300 of FIG. 9 during an additional manufacturing operation. As described herein, the passive component 300 may be integrally formed within the plurality of layers of the substrate 320. Additional structures (e.g., traces or vias) may be coupled to the passive component 300. In an example, vias 360 may be independently coupled to the first electrode 350A and the second electrode 350B. The vias 360 may allow for electrical signals to be routed through different layers of the substrate 320, such as a third layer 323. The passive component 300 may be included in a plurality of passive components. The additional structures, such as a trace, may allow for the passive component 300 to be in electrical communication with other electronic devices, such as the die 110 of FIGS. 1 and 2, the fourth capacitor 130D of FIG. 2, or the external device 160 of FIG. 1.

The passive device 300 may be used in radio-frequency applications. In an example, the passive component 300 may be used in wireless communication devices. The passive component 300 may be included in an RF filter. The passive component 300 may be included in a multi-band system. The passive component 300 may be included in a power splitter. The passive component 300 may have dimensions less than 300 micrometers.

FIG. 11 illustrates a portion of the passive component 1100 during a manufacturing operation. The passive component 1100 may be a capacitor. As described herein, the passive component 1100 may be integrally formed within the plurality of layers of the substrate 1120. The passive component 1100 may be the first capacitor 130A of FIG. 1. The passive component 1100 may include a first layer 1121, a second layer 1122, a substrate 1120, and a first electrode 1150A. The substrate 1120 may include the same material as the substrate 320 of FIGS. 3-10. The substrate 1120 may include the same material as the substrate 120 of FIGS. 1-2. In an example, the first layer 1121 may be the first layer 121 of FIG. 1. The first layer 1121 may be the first layer 310A of FIGS. 3-10. The second layer 1122 may be the second layer 310B of FIGS. 3-10. The first layer 1121 may be the first layer 121 of FIG. 1. The second layer 1122 may be the second layer 122 of FIG. 2.

The first electrode 1150A may be coupled to the substrate 1120. The first electrode 1150A may be formed on the substrate 1120. The first electrode 1150A may be formed on the first layer 1121 of the substrate 1120. The first electrode may be formed in the second layer 1122 of the passive component 300. The first electrode 1150A may be formed on, and thereby coupled with, the substrate 1120. The first electrode 1150A may be formed on the substrate 1120 by a process including electrodepositing, sputtering, electro-less plating, physical deposition, additive processes, and subtractive processes. However, other processes are possible to couple the first electrode 1150A with the substrate 1120, and are anticipated within the scope of this disclosure. The first electrode 1150A may include copper and/or aluminum. The first electrode 1150A may be parallel with the substrate 1120. The passive component 1100 may also include additional materials (e.g., barrier metals, such as titanium) at an interface (e.g., between the substrate 1120 and the first electrode 1150A) configured to enhance material compatibility or to resist etching.

FIG. 12 illustrates a portion of the passive component 1100 of FIG. 11 during an additional manufacturing operation. The passive component 1100 may include the first layer 1121, the second layer 1122, the substrate 1120, and the first electrode 1150A. As shown in FIG. 12, the second layer 1122 may include the substrate 1120. In an example, the substrate 1120 may be coupled to the substrate 1120 of the first layer 1121. The substrate 1120 may be coupled to the first electrode 1150A. The substrate 1120 may be formed in the second layer 1122. The substrate 1120 may be planarized such that a top surface of the substrate 1120, located in the second layer 1122, is coplanar with a top surface of the electrode 1150A.

FIG. 13 illustrates a portion of the passive component 1100 of FIG. 12 during an additional manufacturing operation. The passive component 1100 may include the first layer 1121, the second layer 1122, a third layer 1123, the substrate 1120, a capacitive area 1135, a sacrificial component 1140, and the first electrode 1150A. The third layer 1123 may include the capacitive area 1135 and the sacrificial component 1140. The sacrificial component 1140 may be coupled to, or formed on, the second layer 1122. The sacrificial component 1140 may be coupled to the first electrode 1150A. The sacrificial component 1140 may be coupled to the substrate 1120. The sacrificial component may define the capacitive area 1135. The capacitive area 135 may be a cavity. The capacitive area 135 may have a length (e.g., the dimension along the X-axis of FIG. 13). The length of the capacitive area 135 may be greater than a length of an upper portion of the first electrode 1150A. The passive component 1100 may include a layer of a barrier metal (not shown), such as titanium, between the sacrificial component 1140 of the third layer 1123 and the components located in the second layer 1122 (e.g., the first electrode 1150A or the substrate 1120). The layer of barrier metal may allow for the sacrificial component to be removed without affecting the components located in the second layer 1122. In an example, the sacrificial component 1140 is copper and the barrier metal is titanium. The sacrificial component 1140 may be etched away, and the barrier metal may prevent the etching process from affecting additional components.

FIG. 14 illustrates a portion of the passive component 1100 of FIG. 13 during an additional manufacturing operation. The passive component 1100 may include the first layer 1121, the second layer 1122, the third layer 1123, the substrate 1120, a dielectric component 1130, the capacitive area 1135, the sacrificial component 1140, and the first electrode 1150A. The dielectric component 1130 may be coupled to, or formed on, the first electrode 1150A. The dielectric component 1130 may be coupled to, or formed on, the sacrificial component 1140. The dielectric component 1130 may be included in the third layer 1123 of the passive component 1100. The dielectric component 1130 may have a first dielectric constant (e.g., relative permittivity). The dielectric component 1130 may have a second dielectric constant. The dielectric component 1130 may have additional dielectric constants within a range of 3.0 to 150. The dielectric component 1130 may be a high-κ dielectric. Use of the high-κ dielectric may allow for a decrease in size of the passive component 1100.

The third layer 1123 may include a second dielectric component 1130 (not shown). The second dielectric component 1130 may have a third dielectric constant. The third dielectric constant may be equal to the first dielectric constant or the second dielectric constant. The third dielectric constant may be different than the first dielectric constant or the second dielectric constant. The third layer 1123 may include a resistive component (e.g., the resistive component 330 of FIGS. 3-10).

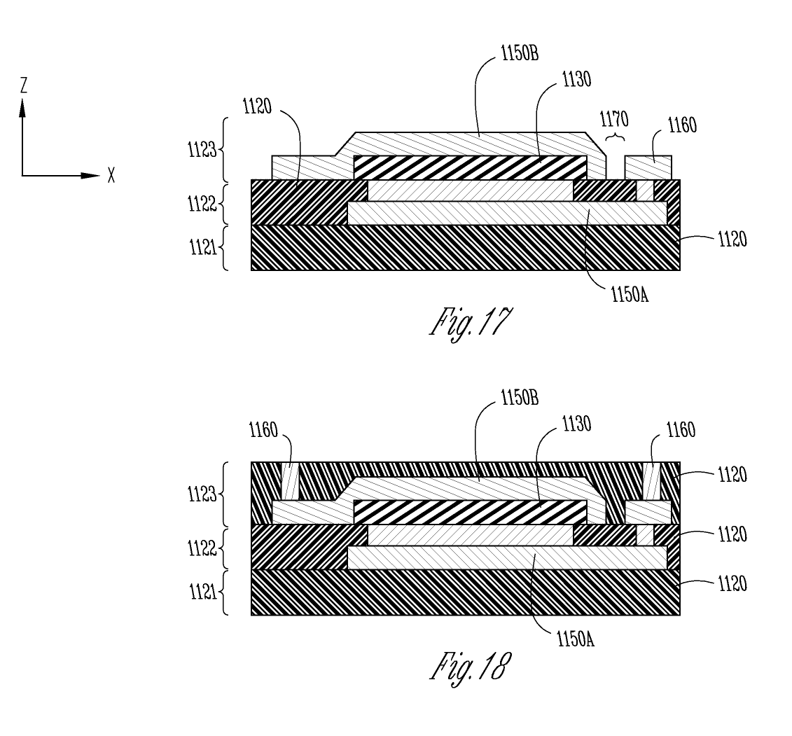

FIG. 15 illustrates a portion of the passive component 1100 of FIG. 14 during an additional manufacturing operation. The passive component 1100 may include the first layer 1121, the second layer 1122, the third layer 1123, the substrate 1120, the dielectric component 1130, the capacitive area 1135, the sacrificial component 1140, and the first electrode 1150A. A portion of the dielectric component 1130 may be removed. The dielectric component 1130 may be planarized. The dielectric component 1130 may be planarized by a process including polishing. The dielectric component 1130 may be planarized such that a top surface of the dielectric component is coplanar with a top surface of the sacrificial component 1140. The portion of the dielectric component 1130 may be removed such that the dielectric component is only located within the capacitive area 1135. Polishing the dielectric component 1130 may allow for increased precision and/or accuracy in the capacitance of the passive component 1100.

FIG. 16 illustrates a portion of the passive component 1100 of FIG. 15 during an additional manufacturing operation. The passive component 1100 may include the first layer 1121, the second layer 1122, the third layer 1123, the substrate 1120, the dielectric component 1130, and the first electrode 1150A. The sacrificial component 1140 of FIGS. 13-15 may be removed from the passive component 1100. As discussed herein, a barrier metal may be used between the sacrificial component 1140 and the components located in the second layer 1122. The sacrificial component 1140 may be removed such that only the dielectric component 1130 remains in the third layer 1123. Removal of the sacrificial component 1140 may expose a portion of the first electrode 1150A and/or the substrate 1120.

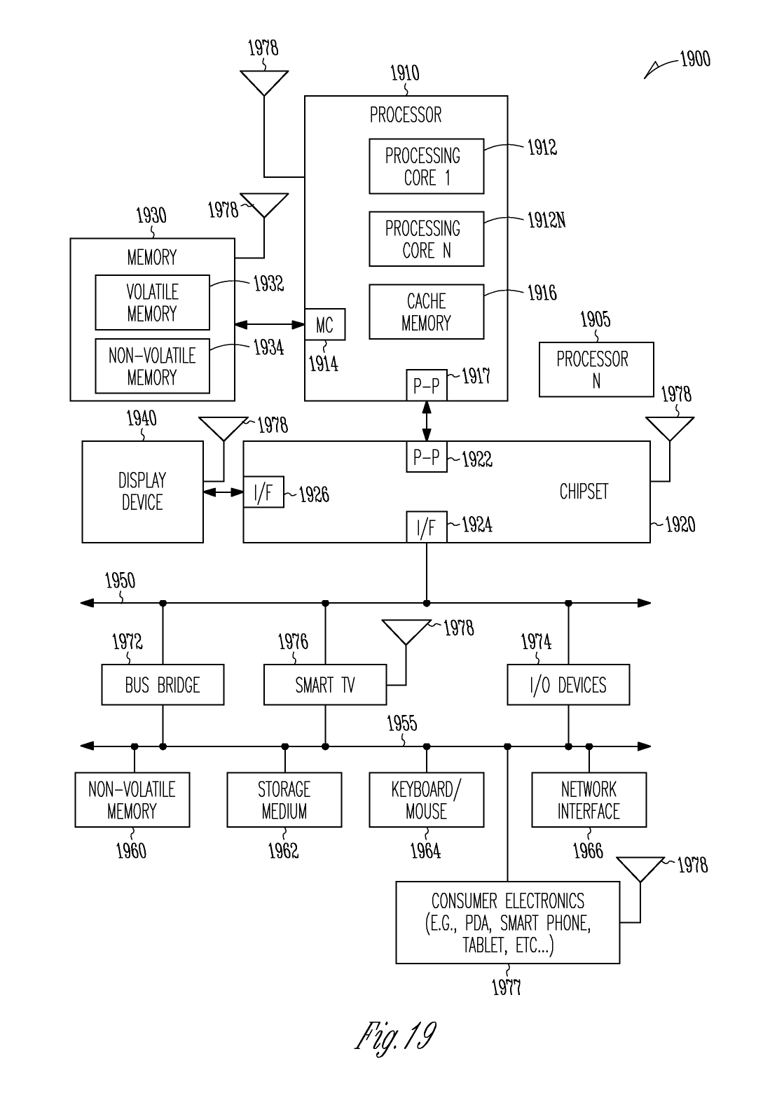

FIG. 17 illustrates a portion of the passive component 1100 of FIG. 16 during an additional manufacturing operation. The passive component 1100 may include the first layer 1121, the second layer 1122, the third layer 1123, the substrate 1120, the dielectric component 1130, the first electrode 1150A, a second electrode 1150B, and one or more vias 1160. The second electrode 1150B may be included in the third layer 1123. The second electrode 1150B may be coupled to the dielectric component 1130. The second electrode 1150B may be coupled to the substrate 1120. As shown, the second electrode 1150B may be coupled to the top portion of the dielectric component 1130. The second electrode 1150B may be coupled to at least one side of the dielectric component 1130. The second electrode 1150B may substantially enclose (e.g., surround or encase) the dielectric component 1130. The second electrode 1150B may entirely enclose the dielectric component 1130.

Additional structures (e.g., traces or vias) may be coupled to the passive component 1100. In an example, a first via of the one or more vias 1160 may be coupled to a portion of the first electrode 1150A. A second via may be coupled to the second electrode 1150B (e.g., as shown by the one or more vias 1160 of FIG. 18). The one or more vias 1160 may allow for electrical signals to be routed through different layers of the substrate 1120, such as the third layer 1123. The passive component 1100 may be included in the plurality of passive components. The additional structures, such as a trace, may allow for the passive component 1100 to be in electrical communication with other electronic devices, such as the die 110 of FIGS. 1 and 2, the fourth resistor 140D of FIG. 2, or the external device 160 of FIG. 1.

A cavity 1170 may be included in the third layer 1123. The cavity 1170 may provide a gap between the second electrode 1150B and components connected to the first electrode 1150A (e.g., the via 1160) such that the first electrode 1150A and the second electrode 1150B are not allowed to be in electrical communication. Stated another way, the cavity 1170 may prevent electrical shorting between the first electrode 1150A and the second electrode 1150B. The cavity 1170 may be filled with the substrate 1120.

FIG. 18 illustrates a portion of the passive component 1100 of FIG. 17 during an additional manufacturing operation. The passive component 1100 may include the first layer 1121, the second layer 1122, the third layer 1123, the substrate 1120, the dielectric component 1130, the first electrode 1150A, the second electrode 1150B, and the one or more vias 1160. As discussed herein, the passive component 1100 may be a capacitor. The dielectric component 1130 may store electrical energy when a voltage source is applied to the first electrode 1150A and the second electrode 1150B.

The third layer 1123 may include the substrate 1120. The substrate 1120 may fill the cavity 1170 (shown in FIG. 17). The substrate 1120 may be coupled with the second electrode 1150B. The substrate 1120 may entirely enclose the second electrode 1150B. The substrate 1120 may substantially enclose the second electrode 1150B. The substrate 1120 of the third layer 1123 may be coupled with components located on the second layer 1122 (e.g., the substrate 1120). The substrate 1120 of the third layer 1123 may provide a surface to form additional structures or layers of the semiconductor device 100. Stated another way, the substrate 1120 of the third layer 1123 may be a planar surface that is configured to allow additional structures or components to be formed onto the third layer 1123 (e.g., traces for routing electrical signals to the passive component 1100).

The one or more vias 1160 may be formed within the third layer 1123. As shown in FIG. 18, a first via may be coupled to the first electrode 1150A and a second via may be coupled to the second electrode 1150B. The first via may be included in the first electrode 1150A. The second via may be included in the second electrode 1150B. The one or more vias 1160 may be exposed in substrate 1120 of the third layer 1123. The first electrode 1150A and the second electrode 1150B may have the same height with respect to the first layer 1121. Stated another way, a top portion of the one or more vias 1160 may be coplanar with a top portion of the third layer 1123. The exposed portions of one or more vias 1160 may be coupled to additional structures (e.g., traces) to allow for the electrical communication of the passive component 1100 with other components (e.g., the die 110 of FIGS. 1-2).

The passive component 1100 may be used in radio-frequency applications. In an example, the passive component 1100 may be used in wireless communication devices. The passive component 1100 may be included in an RF filter. The passive component 1100 may be included in a multi-band system. The passive component may be used in high-frequency applications, such as in the range of 500 megahertz to 1.5 terahertz.

FIG. 19 illustrates a system level diagram, depicting an example of an electronic device (e.g., system) including the semiconductor device 100 as described in the present disclosure. FIG. 19 is included to show an example of a higher level device application for the semiconductor device 100. In one embodiment, system 1900 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance or any other type of computing device. In some embodiments, system 1900 is a system on a chip (SOC) system.

In one embodiment, processor 1910 has one or more processor cores 1912 and 1912N, where 1912N represents the Nth processor core inside processor 1910 where N is a positive integer. In one embodiment, system 1900 includes multiple processors including 1910 and 1905, where processor 1905 has logic similar or identical to the logic of processor 1910. In some embodiments, processing core 1912 includes, but is not limited to, pre-fetch logic to fetch instructions, decode logic to decode the instructions, execution logic to execute instructions and the like. In some embodiments, processor 1910 has a cache memory 1916 to cache instructions and/or data for system 1900. Cache memory 1916 may be organized into a hierarchal structure including one or more levels of cache memory.

In some embodiments, processor 1910 includes a memory controller 1914, which is operable to perform functions that enable the processor 1910 to access and communicate with memory 1930 that includes a volatile memory 1932 and/or a non-volatile memory 1934. In some embodiments, processor 1910 is coupled with memory 1930 and chipset 1920. Processor 1910 may also be coupled to a wireless antenna 1978 to communicate with any device configured to transmit and/or receive wireless signals. In one embodiment, an interface for wireless antenna 1978 operates in accordance with, but is not limited to, the IEEE 802.11 standard and its related family, Home Plug AV (HPAV), Ultra Wide Band (UWB), Bluetooth, WiMax, or any form of wireless communication protocol.

In some embodiments, volatile memory 1932 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 1934 includes, but is not limited to, flash memory, phase change memory (PCM), read-only memory (ROM), electrically erasable programmable read-only memory (EEPROM), or any other type of non-volatile memory device.

Memory 1930 stores information and instructions to be executed by processor 1910. In one embodiment, memory 1930 may also store temporary variables or other intermediate information while processor 1910 is executing instructions. In the illustrated embodiment, chipset 1920 connects with processor 1910 via Point-to-Point (PtP or P-P) interfaces 1917 and 1922. Chipset 1920 enables processor 1910 to connect to other elements in system 1900. In some embodiments of the example system, interfaces 1917 and 1922 operate in accordance with a PtP communication protocol such as the Intel® QuickPath Interconnect (QPI) or the like. In other embodiments, a different interconnect may be used.

In some embodiments, chipset 1920 is operable to communicate with processor 1910, 1905N, display device 1940, and other devices, including a bus bridge 1972, a smart TV 1976, I/O devices 1974, nonvolatile memory 1960, a storage medium (such as one or more mass storage devices) 1962, a keyboard/mouse 1964, a network interface 1966, and various forms of consumer electronics 1977 (such as a PDA, smart phone, tablet etc.), etc. In one embodiment, chipset 1920 couples with these devices through an interface 1924. Chipset 1920 may also be coupled to a wireless antenna 1978 to communicate with any device configured to transmit and/or receive wireless signals.

Chipset 1920 connects to display device 1940 via interface 1926. Display 1940 may be, for example, a liquid crystal display (LCD), a plasma display, cathode ray tube (CRT) display, or any other form of visual display device. In some embodiments of the example system, processor 1910 and chipset 1920 are merged into a single SOC. In addition, chipset 1920 connects to one or more buses 1950 and 1955 that interconnect various system elements, such as I/O devices 1974, nonvolatile memory 1960, storage medium 1962, a keyboard/mouse 1964, and network interface 1966. Buses 1950 and 1955 may be interconnected together via a bus bridge 1972.

In one embodiment, mass storage device 1962 includes, but is not limited to, a solid state drive, a hard disk drive, a universal serial bus flash memory drive, or any other form of computer data storage medium. In one embodiment, network interface 1966 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra Wide Band (UWB), Bluetooth, WiMax, or any form of wireless communication protocol.

While the modules shown in FIG. 6 are depicted as separate blocks within the system 1900, the functions performed by some of these blocks may be integrated within a single semiconductor circuit or may be implemented using two or more separate integrated circuits. For example, although cache memory 1916 is depicted as a separate block within processor 1910, cache memory 1916 (or selected aspects of 1916) can be incorporated into processor core 1912.

### Various Notes

The above description includes references to the accompanying drawings, which form a part of the detailed description. The drawings show, by way of illustration, specific embodiments in which the present subject matter may be practiced. These embodiments are also referred to herein as “examples.” Such examples may include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Geometric terms, such as “parallel”, “perpendicular”, “round”, or “square”, are not intended to require absolute mathematical precision, unless the context indicates otherwise. Instead, such geometric terms allow for variations due to manufacturing or equivalent functions. For example, if an element is described as “round” or “generally round,” a component that is not precisely circular (e.g., one that is slightly oblong or is a many-sided polygon) is still encompassed by this description.

Method examples described herein may be machine or computer-implemented at least in part. Some examples may include a computer-readable medium or machine-readable medium encoded with instructions operable to configure an electronic device to perform methods as described in the above examples. An implementation of such methods may include code, such as microcode, assembly language code, a higher-level language code, or the like. Such code may include computer readable instructions for performing various methods. The code may form portions of computer program products. Further, in an example, the code may be tangibly stored on one or more volatile, non-transitory, or non-volatile tangible computer-readable media, such as during execution or at other times. Examples of these tangible computer-readable media may include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments may be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments may be combined with each other in various combinations or permutations. The scope of the present subject matter should be determined with reference to the appended claims, along with the full scope of equivalents to which such claims are entitled.

1. A semiconductor device, comprising:
a plurality of layers of a substrate;
a die coupled to at least one of the plurality of layers of the substrate;
a passive electrical component integrally formed within the layers of the substrate; and
one or more conductors configured to allow electrical communication between the passive electrical component and the die, wherein the one or more conductors are integrally formed within the plurality of layers of the substrate.

2. The semiconductor package of claim 1, wherein the passive component is in electrical communication with an external device.

3. The semiconductor package of claim 1, wherein the passive electrical component is included in a plurality of passive electrical components.

4. The semiconductor package of claim 1, wherein the passive component is a resistor.

5. The semiconductor package of claim 4, wherein the resistor includes:
a resistive component formed from a portion of a layer of the substrate; and
a first electrode and a second electrode coupled to the resistive component such that the first and second electrodes are in electrical communication through the resistive component.

6. The semiconductor package of claim 5, wherein the layer of the substrate is a first layer of the substrate and further comprising a second layer of the substrate coupled to the first layer of the substrate, the resistive component, and the first and second electrodes, wherein at least a portion of the first electrode and the second electrode are exposed by the second layer of the substrate.

7. The semiconductor package of claim 4, wherein the resistive component comprises a material including: titanium nitride, combinations of titanium and nitrogen in a form, nickel, nickel phosphorous, tantalum, and bismuth.

8. The semiconductor package of claim 1, wherein the passive component is a capacitor.

9. The semiconductor package of claim 8, wherein the capacitor includes:
a first package layer comprising the substrate;
a second package layer comprising:
a first electrode coupled to the first package layer;
a second layer of the substrate substantially surrounding the first electrode; and
a third package layer comprising:
a dielectric component coupled to the first electrode;
a second electrode coupled to the dielectric component
a third layer of the substrate coupled to the second electrode.

10. The semiconductor package of claim 9, wherein the dielectric component has a first dielectric constant and further comprising a second dielectric component having a second dielectric constant.

11. The semiconductor package of claim 10, wherein the first dielectric constant is different than the second dielectric constant.

12. The semiconductor package of claim 10, wherein the first dielectric component and the second dielectric component are located on the same layer of the substrate.

13. The semiconductor package of claim 9, wherein the second electrode substantially surrounds the dielectric component.

14. The semiconductor package of claim 9, wherein the first electrode and the second electrode have the same height with respect to the layer of the substrate.

15. The semiconductor package of claim 1, wherein the semiconductor package is a first semiconductor package and the first semiconductor package is coupled to a second semiconductor package.

16. A semiconductor device, comprising:
a plurality of layers of a substrate;
a die coupled to at least one of the plurality of layers of the substrate;
a resistor integrally formed within the layers of the substrate, wherein the resistor includes:
a resistive component formed from a portion of a layer of the substrate, and
a first electrode and a second electrode coupled to the resistive component such that the first and second electrodes are in electrical communication through the resistive component; and
one or more conductors configured to establish an electrical communication pathway between the resistor and the die, wherein the one or more conductors are integrally formed within the plurality of layers of the substrate.

17. The semiconductor device of claim 16, wherein a length of the resistive component is at least 1.5 times greater than a width of the resistive component.

18. The semiconductor device of claim 16, wherein the layer of the substrate is a first layer of the substrate and further comprising a second layer of the substrate coupled to the first layer of the substrate, the resistive component, and the first and second electrodes, wherein at least a portion of the first electrode and the second electrode are exposed by the second layer of the substrate.

19. The semiconductor device of claim 16, wherein the resistive component comprises a material including: Titanium nitride, Nickel Phosphorous, Bismuth.

20. A semiconductor device, comprising:
a plurality of layers of a substrate;
a die coupled to at least one of the plurality of layers of the substrate;
a capacitor integrally formed within the layers of the substrate wherein the capacitor includes:
a first electrode formed from a portion of a first layer of the plurality of layers of the substrate,
a dielectric component coupled to the first electrode, and
a second electrode coupled to the dielectric component; and
one or more conductors configured to allow electrical communication between the capacitor and the die, wherein the one or more conductors are integrally formed within the plurality of layers of the substrate.

21. The semiconductor package of claim 20, wherein the dielectric component has a first dielectric constant and further comprising a second layer of the plurality of layers of the substrate that is coplanar with the dielectric component, wherein the first dielectric component has a first dielectric constant and the second layer has a second dielectric constant.

22. The semiconductor package of claim 21, wherein the first dielectric constant is different than the second dielectric constant.

23. The semiconductor package of claim 21, wherein the first dielectric component and the second dielectric component are located on the same layer of the substrate.

24. The semiconductor package of claim 20, wherein the second electrode substantially surrounds the dielectric component.

25. A method for integrally forming a passive component within a package, comprising:
depositing a resistive component on a first layer of substrate;
depositing a layer of conductive material on the resistive component; and
removing a portion of the layer of conductive material.

26. The method of claim 25, wherein the layer of conductive material is a first layer of conductive material, and further comprising depositing a second layer of conductive material.

27. The method of claim 25, further comprising depositing a second layer of substrate, wherein the second layer of substrate is coupled to the first layer of substrate, the first electrode, the second electrode, and the resistive component.

28. The method of claim 25, wherein the depositing the resistive component or depositing the layer of conductive material includes depositing the resistive component or the conductive material using a process including: electrodepositing, electroless plating, physical depositing, additive processes, and subtractive processes.

29. A method for integrally forming a passive component within a package, comprising:
depositing a first electrode on a first layer of substrate;
depositing a dielectric component on the first electrode; and
depositing a second electrode on the dielectric component.

30. The method of claim 29, further comprising depositing a second layer of substrate, wherein the second layer of substrate is coupled to the first electrode and the first layer of substrate.

31. The method of claim 29, wherein depositing the first electrode, depositing the dielectric component, or depositing the second electrode includes depositing the first electrode, the dielectric component, or the second electrode includes using a process including: electrodepositing, electroless plating, physical depositing, additive processes, and subtractive processes.
